(19) United States
(12) Patent Application Publication
(10) Pub. No.: US 2014/0259655 A1
(43) Pub. Date: Sep. 18, 2014

(54) PRODUCTION METHOD OF ELECTROSTATIC CAPACITANCE ELEMENT

(71) Applicant: Sony Corporation, Tokyo (JP)

(72) Inventor: Noritaka Sato, Kanagawa (JP)

(21) Appl. No.: 14/351,464

(22) PCT Filed: Oct. 2, 2012
(86) PCT No.: PCT/JP2012/075485

§ 371 Date: Apr. 11, 2014

(30) Foreign Application Priority Data
Oct. 20, 2011 (JP) 2011-230919

(51) Int. Cl. H01L 21/02

(52) U.S. Cl. CPC H01L 21/02
USPC 29/832

(57) ABSTRACT

Provided is a production method of an electrostatic capacitance element, including preparing a dielectric sheet on which a conductor is not being applied, and a mask that has at least one basic pattern shape, making a basic-pattern green sheet by applying the conductor on the dielectric sheet through the mask, making a rotated basic-pattern green sheet in which the basic-pattern green sheet is rotated, making a laminate of the basic-pattern green sheet and the rotated basic-pattern green sheet, making a reversed basic-pattern green sheet by reversing at least one of the basic-pattern green sheet or rotated basic-pattern green sheet, laminating the reversed basic-pattern green sheet on the laminate with a dielectric sheet, on which a conductor is not being applied, interposed therebetween, and performing compression-bonding and baking treatments of a laminate of the basic-pattern green sheet, the rotated basic-pattern green sheet, the dielectric sheet and the reversed basic-pattern green sheet.

### TECHNICAL FIELD

The present disclosure relates to a production method of an electrostatic capacitance element, particularly, to a production method of an electrostatic capacitance element that reduces the number of internal electrode patterns and improves the productivity.

### BACKGROUND ART

In recent years, due to the downsizing and high reliability of electronic equipment, it has been desired to develop an electrostatic capacitance element that is downsized and has a high performance, as an electronic component used in the electronic equipment. The inventors have already proposed a production technique that enlarges an increase-decrease space in the area of an internal electrode to be formed on the same plane as a dielectric layer, and thereby broadens the design flexibility of the internal electrode, capacitance value and others of an electrostatic capacitance device (for example, see Patent Literature 1).

Patent Literature 1 provides a variable capacitance device, and in a production method of this variable capacitance device, a sheet member composed of a dielectric material is prepared, and on this sheet member, a conductive paste that is a paste made from metal fine powder such as Pd, Pd/Ag or Ni, is applied.

The conductive paste is applied (by silk-printing or the like) on one surface of the sheet member composed of the dielectric material, through a mask on which an opening corresponding to the shape (for example, a rectangular shape) of an internal electrode is formed, and then the internal electrode is formed.

In the production method described in Patent Literature 1, five electrode-attached sheet members are laminated in a predetermined order such that the internal electrodes and the sheet members are alternately arranged, and then a sheet member that is separately prepared and on which an internal electrode is not being formed is laminated on the surface of the side on which the internal electrode is exposed. Thereafter, a variable capacitance device body is made by compression-bonding the laminate member and baking this compression-bonded member at a high temperature in a reducing atmosphere to unite the sheet members and the conductive paste layers (internal electrodes). Then, an external terminal is attached at a predetermined position on a side surface of the device body 10.

### CITATION LIST

### Patent Literature

Patent Literature 1: JP 2011-119482A

### SUMMARY OF INVENTION

### Technical Problem

However, the technique described in Patent Literature 1 is mainly intended to further broaden the design flexibility of the internal capacitance, capacitance value and others of the variable capacitance device that is configured such that plural variable capacitance capacitors are connected in series, and does not provide a concrete improvement of the production method.

In a conventional production method, a mixture of dielectric powder and organic substance binder is applied on a simple sheet so that a dielectric sheet (hereinafter, this sheet is referred to as a “white sheet”) is made. Thereafter, a paste made from conductive powder of a base metal such as Ni is applied on this white sheet, through a mask on which an opening corresponding to the shape (for example, a rectangular shape) of an internal electrode pattern is formed, and thereby, a sheet on which a conductor of a capacitor electrode has been applied (hereinafter, this sheet is referred to as a “green sheet (GS)”) is made.

Here, in the case of making a capacitor array in which plural capacitors as unit elements are connected in series in the laminating direction, or a capacitor array in which plural capacitor blocks, in each of which plural capacitors as unit elements are connected in series in the laminating direction, are laminated and connected in parallel, many internal electrode patterns are necessary. Many internal electrode patterns require that green sheets are made by the number of the internal electrode patterns, resulting in a difficulty in the making accuracy management for the green sheets. Furthermore, there is a problem in that many kinds of green sheets increase processes of laminating them and also increase the facility investment therefor, resulting in a decrease in productivity.

Still, even in the conventional production method, a green sheet on which one electrode pattern is formed is used as a green sheet with a different pattern, for example, by 180°-rotation. That is, green sheets with one kind of electrode pattern are used as green sheets with two kinds of internal electrode patterns. However, in the conventional method, the 180°-rotation is the limit, and a making of a green sheet with a further-rotated electrode pattern requires a process of producing a green sheet with a different electrode pattern. Therefore, the quality control of the production process therefor and the enlargement of the facility are required, and the cost increase therefor cannot be resolved.

Hence, an object of the present disclosure is to provide a production method of an electrostatic capacitance element that is more efficient, by reducing the number of internal electrode patterns of green sheets as much as possible, and making green sheets with substantially plural kinds of internal electrode patterns from green sheets with one internal electrode pattern.

### Solution to Problem

A production method of an electrostatic capacitance element according to the present disclosure, which solves the above problem, includes preparing a dielectric sheet on which a conductor is not being applied, and a mask that has at least one basic pattern shape for applying the conductor on the dielectric sheet, making a basic-pattern green sheet by applying the conductor on the dielectric sheet through the mask, and making a rotated basic-pattern green sheet in which the basic-pattern green sheet is rotated.

Further, it includes laminating the basic-pattern green sheet and the rotated basic-pattern green sheet, and making a reversed basic-pattern green sheet by reversing at least one green sheet of the basic-pattern green sheet or the rotated basic-pattern green sheet, the reversed basic-pattern green sheet being different from the basic-pattern green sheet or the rotated basic-pattern green sheet.

In addition, it includes laminating the reversed basic-pattern green sheet on a laminate with a dielectric sheet, on which a conductor is not being applied, interposed therebetween, the laminate being resulting from laminating the basic-pattern green sheet and the rotated basic-pattern green sheet, and performing compression-bonding and baking treatments of a laminate of the basic-pattern green sheet, the rotated basic-pattern green sheet, the dielectric sheet and the reversed basic-pattern green sheet.

Also, it includes printing an external electrode on a side surface of the laminate of the basic-pattern green sheet, the rotated basic-pattern green sheet, the dielectric sheet and the reversed basic-pattern green sheet, and then performing a baking treatment. Further, as necessary, it includes laminating a reinforcement dielectric sheet on an upper part and a lower part of the laminate of the basic-pattern green sheet, the rotated basic-pattern green sheet, the dielectric sheet and the reversed basic-pattern green sheet.

Another embodiment of the present disclosure includes preparing a dielectric sheet and a mask that has a predetermined pattern shape for applying a conductor on the dielectric sheet, making a basic-pattern green sheet by applying the conductor on the dielectric sheet through the mask, making a 90°-rotated basic-pattern green sheet by rotating the basic-pattern green sheet by 90°, making a 180°-rotated basic-pattern green sheet by rotating the basic-pattern green sheet by 180°, and making a 270°-rotated basic-pattern green sheet by rotating the basic-pattern green sheet by 270°. In addition, it includes laminating the basic-pattern green sheet, the 90°-rotated basic-pattern green sheet, the 180°-rotated basic-pattern green sheet and the 270°-rotated basic-pattern green sheet, and includes laminating a reinforcement dielectric sheet on which a conductor is not being applied, on an upper part and a lower part of the four laminated green sheets, and then performing compression-bonding and baking treatments.

### Advantageous Effects of Invention

According to the present disclosure, a green sheet with one internal electrode pattern is usefully utilized, and therefore the making accuracy can be managed with relative ease, particularly in a production method of an electrostatic capacitance element in which many capacitors are connected in series. Furthermore, in the production method of the electrostatic capacitance element, it is possible to reduce costs for production facilities and to have a very high productivity.

### BRIEF DESCRIPTION OF DRAWINGS

FIG. 1A is a diagram showing an external view of a single conventionally-existing electrostatic capacitance element that has a parallel connection.

FIG. 1B is a diagram showing a cross-section view of the single conventionally-existing electrostatic capacitance element that has a parallel connection.

FIG. 1C is a diagram showing an equivalent circuit of the single conventionally-existing electrostatic capacitance element that has a parallel connection.

FIG. 2A is a diagram showing an example of a basic-pattern green sheet that is used in the electrostatic capacitance element in FIG. 1.

FIG. 2B is a diagram showing an example of a green sheet that is used in the electrostatic capacitance element in FIG. 1 and in which the basic-pattern green sheet is rotated by 180°.

FIG. 3 is a diagram for explaining an outline of a production method of the electrostatic capacitance element shown in FIG. 1.

FIG. 4A is a diagram showing an external view of an electrostatic capacitance element that is made using conventionally-existing green sheets with two patterns and in which two capacitors are connected in series.

FIG. 4B is a diagram showing a cross-section view of the electrostatic capacitance element that is made using the conventionally-existing green sheets with the two patterns and in which the two capacitors are connected in series.

FIG. 4C is a diagram showing an equivalent circuit of the electrostatic capacitance element that is made using the conventionally-existing green sheets with the two patterns and in which the two capacitors are connected in series.

FIG. 5A is a diagram showing an example of a basic-pattern green sheet that is used in the electrostatic capacitance element shown in FIG. 4.

FIG. 5B is a diagram showing an example of a green sheet that is used in the electrostatic capacitance element shown in FIG. 4 and in which the basic pattern is rotated by 180°.

FIG. 5C is a diagram showing an example of a second-pattern green sheet that is used in the electrostatic capacitance element in the figure.

FIG. 6 is a diagram for explaining an outline of a production method of the electrostatic capacitance element shown in FIG. 4.

FIG. 7A is a diagram showing an external view of an electrostatic capacitance element that is made using conventionally-existing green sheets with two patterns and in which three capacitors are connected in series.

FIG. 7B is a diagram showing a cross-section view of the electrostatic capacitance element that is made using the conventionally-existing green sheets with the two patterns and in which the three capacitors are connected in series.

FIG. 7C is a diagram showing an equivalent circuit of the electrostatic capacitance element that is made using the conventionally-existing green sheets with the two patterns and in which the three capacitors are connected in series.

FIG. 8 is a diagram showing an example of a fourth green sheet that is used in production of the electrostatic capacitance element in FIG. 7 and in which the second pattern shown in FIG. 5C is rotated by 180°.

FIG. 9 is a diagram for explaining an outline of a production method of the electrostatic capacitance element shown in FIG. 7.

FIG. 10A is a diagram showing an external view of an electrostatic capacitance element that is an example of a first embodiment of the present disclosure and in which two capacitors are connected in series.

FIG. 10B is a diagram showing a cross-section view of the electrostatic capacitance element that is the example of the first embodiment of the present disclosure and in which the two capacitors are connected in series.

FIG. 10C is a diagram showing an equivalent circuit of the electrostatic capacitance element that is the example of the first embodiment of the present disclosure and in which the two capacitors are connected in series.

FIG. 11A is a diagram showing an example of a basic-pattern green sheet that is used in the electrostatic capacitance element in FIG. 10.

FIG. 11B is a diagram showing an example of a 180°-rotated green sheet that is used in the electrostatic capacitance element in FIG. 10 and in which the basic pattern is rotated by 180°.

FIG. 11C is a diagram showing an example of a reversed green sheet that is used in the electrostatic capacitance element in FIG. 10 and that is made by reversing the basic pattern.

FIG. 12 is a diagram for explaining an outline of a production method of the electrostatic capacitance element shown in FIG. 10.

FIG. 13 is a process diagram showing a procedure of the production method of the electrostatic capacitance element shown in FIG. 10.

FIG. 14A is a diagram showing an external view of an electrostatic capacitance element that is a first modification of the first embodiment of the present disclosure and in which three capacitors are connected in series.

FIG. 14B is a diagram showing a cross-section view of the electrostatic capacitance element that is the first modification of the first embodiment of the present disclosure and in which the three capacitors are connected in series.

FIG. 14C is a diagram showing an equivalent circuit of the electrostatic capacitance element that is the first modification of the first embodiment of the present disclosure and in which the three capacitors are connected in series.

FIG. 15 is a diagram showing an example of a fourth green sheet that is used in the modification of the first embodiment of the present disclosure shown in FIG. 14 and in which the green sheet in FIG. 11B, in which the basic pattern is rotated by 180°, is further reversed.

FIG. 16 is a diagram for explaining an outline of a production method of the electrostatic capacitance element shown in FIG. 14.

FIG. 17 is a process diagram showing a procedure of the production method of the electrostatic capacitance element shown in FIG. 14.

FIG. 18A is a diagram showing an external view of an electrostatic capacitance element that is a second modification of the first embodiment of the present disclosure and in which seven capacitors are connected in series.

FIG. 18B is a diagram showing a cross-section view of the electrostatic capacitance element that is the second modification of the first embodiment of the present disclosure and in which the seven capacitors are connected in series.

FIG. 18C is a diagram showing an equivalent circuit of the electrostatic capacitance element that is the second modification of the first embodiment of the present disclosure and in which the seven capacitors are connected in series.

FIG. 19A is a diagram showing an example of a basic-pattern green sheet that is used in the second modification of the first embodiment of the present disclosure shown in FIG. 18.

FIG. 19B is a diagram showing an example of a 180°-rotated green sheet that is used in the second modification of the first embodiment of the present disclosure shown in FIG. 18 and in which the basic pattern is rotated by 180°.

FIG. 19C is a diagram showing an example of a reversed basic-pattern green sheet that is used in the second modification of the first embodiment of the present disclosure shown in FIG. 18 and that is made by reversing the basic pattern.

FIG. 19D is a diagram showing an example of a 180°-rotated and reversed green sheet that is used in the second modification of the first embodiment of the present disclosure shown in FIG. 18 and in which the basic pattern is rotated by 180° and thereafter is reversed.

FIG. 20E is a diagram showing an example of a second-pattern green sheet that is used in the second modification of the first embodiment of the present disclosure shown in FIG. 18.

FIG. 20F is a diagram showing an example of a 180°-rotated second-pattern green sheet that is used in the second modification of the first embodiment of the present disclosure shown in FIG. 18 and in which the second pattern is rotated by 180°.

FIG. 20G is a diagram showing an example of a reversed second-pattern green sheet that is used in the second modification of the first embodiment of the present disclosure shown in FIG. 18 and that is made by reversing the second pattern.

FIG. 20H is a diagram showing an example of a 180°-rotated and reversed second-pattern green sheet that is used in the second modification of the first embodiment of the present disclosure shown in FIG. 18 and that is made by rotating the second pattern by 180° and thereafter reversing it.

FIG. 21 is a diagram for explaining an outline of a production method of the electrostatic capacitance element shown in FIG. 18.

FIG. 22 is a process diagram showing a procedure of the production method of the electrostatic capacitance element shown in FIG. 18.

FIG. 23A is a diagram showing an external view of an electrostatic capacitance element that is an example of a second embodiment of the present disclosure and in which three capacitors are connected in series.

FIG. 23B is a diagram showing a cross-section view of the electrostatic capacitance element that is the example of the second embodiment of the present disclosure and in which the three capacitors are connected in series.

FIG. 23C is a diagram showing an equivalent circuit of the electrostatic capacitance element that is the example of the second embodiment of the present disclosure and in which the three capacitors are connected in series.

FIG. 24A is a diagram showing an example of a basic-pattern green sheet that is used in the example of the second embodiment of the present disclosure shown in FIG. 23.

FIG. 24B is a diagram showing an example of a 90°-rotated basic-pattern green sheet that is used in the example of the second embodiment of the present disclosure shown in FIG. 23 and in which the basic pattern is rotated by 90°.

FIG. 24C is a diagram showing an example of a 180°-rotated basic-pattern green sheet that is used in the example of the second embodiment of the present disclosure shown in FIG. 23 and in which the basic pattern is rotated by 180°.

FIG. 24D is a diagram showing an example of a 270°-rotated basic-pattern green sheet that is used in the example of the second embodiment of the present disclosure shown in FIG. 23 and in which the basic pattern is rotated by) 270° (−90°).

FIG. 25 is a diagram for explaining an outline of a production method of the electrostatic capacitance element shown in FIG. 23.

FIG. 26 is a process diagram showing a procedure of the production method of the electrostatic capacitance element shown in FIG. 23.

FIG. 27A is a diagram showing an external view of an electrostatic capacitance element that is a first modification of the second embodiment of the present disclosure and in which seven green sheets are used and six capacitors are connected in two-parallel and three-series.

FIG. 27B is a diagram showing a cross-section view of the electrostatic capacitance element that is the first modification of the second embodiment of the present disclosure and in which the seven green sheets are used and the six capacitors are connected in two-parallel and three-series.

FIG. 27C is a diagram showing an equivalent circuit of the electrostatic capacitance element that is the first modification of the second embodiment of the present disclosure and in which the seven green sheets are used and the six capacitors are connected in two-parallel and three-series.

FIG. 27D is a diagram showing an internal circuit of the electrostatic capacitance element that is the first modification of the second embodiment of the present disclosure and in which the seven green sheets are used and the six capacitors are connected in two-parallel and three-series.

FIG. 28 is a diagram for explaining an outline of a production method of the electrostatic capacitance element shown in FIG. 27.

FIG. 29 is a process diagram showing a procedure of the production method of the electrostatic capacitance element shown in FIG. 27.

FIG. 30A is a diagram showing an external view of an electrostatic capacitance element that is a second modification of the second embodiment of the present disclosure and in which eight green sheets are used and six capacitors are connected in two-parallel and three-series.

FIG. 30B is a diagram showing a cross-section view of the electrostatic capacitance element that is the second modification of the second embodiment of the present disclosure and in which the eight green sheets are used and the six capacitors are connected in two-parallel and three-series.

FIG. 30C is a diagram showing an equivalent circuit of the electrostatic capacitance element that is the second modification of the second embodiment of the present disclosure and in which the eight green sheets are used and the six capacitors are connected in two-parallel and three-series.

FIG. 30D is a diagram showing an internal circuit of the electrostatic capacitance element that is the second modification of the second embodiment of the present disclosure and in which the eight green sheets are used and the six capacitors are connected in two-parallel and three-series.

FIG. 31 is a diagram for explaining an outline of a production method of the electrostatic capacitance element shown in FIG. 30.

FIG. 32 is a process diagram showing a procedure of the production method of the electrostatic capacitance element shown in FIG. 30.

FIG. 33A is a diagram showing an external view of an electrostatic capacitance element that is a third modification of the second embodiment of the present disclosure and in which ten green sheets are used and nine capacitors are connected in three-parallel and three-series.

FIG. 33B is a diagram showing a cross-section view of the electrostatic capacitance element that is the third modification of the second embodiment of the present disclosure and in which the ten green sheets are used and the nine capacitors are connected in three-parallel and three-series.

FIG. 33C is a diagram showing an equivalent circuit of the electrostatic capacitance element that is the third modification of the second embodiment of the present disclosure and in which the ten green sheets are used and the nine capacitors are connected in three-parallel and three-series.

FIG. 33D is a diagram showing an internal circuit of the electrostatic capacitance element that is the third modification of the second embodiment of the present disclosure and in which the ten green sheets are used and the nine capacitors are connected in three-parallel and three-series.

FIG. 34 is a diagram for explaining an outline of a production method of the electrostatic capacitance element shown in FIG. 33.

FIG. 35 is a process diagram showing a procedure of the production method of the electrostatic capacitance element shown in FIG. 33.

FIG. 36A is a diagram showing an external view of an electrostatic capacitance element that is a fourth modification of the second embodiment of the present disclosure and in which twelve green sheets are used and nine capacitors are connected in three-parallel and three-series.

FIG. 36B is a diagram showing a cross-section view of the electrostatic capacitance element that is the fourth modification of the second embodiment of the present disclosure and in which the twelve green sheets are used and the nine capacitors are connected in three-parallel and three-series.

FIG. 36C is a diagram showing an equivalent circuit of the electrostatic capacitance element that is the fourth modification of the second embodiment of the present disclosure and in which the twelve green sheets are used and the nine capacitors are connected in three-parallel and three-series.

FIG. 36D is a diagram showing an internal circuit of the electrostatic capacitance element that is the fourth modification of the second embodiment of the present disclosure and in which the twelve green sheets are used and the nine capacitors are connected in three-parallel and three-series.

FIG. 37 is a diagram for explaining an outline of a production method of the electrostatic capacitance element shown in FIG. 36.

FIG. 38 is a process diagram showing a procedure of the production method of the electrostatic capacitance element shown in FIG. 36.

FIG. 39A is a diagram showing an external view of an electrostatic capacitance element that is an example of a third embodiment of the present disclosure, that is made using eight green sheets, and in which seven capacitors are connected in series.

FIG. 39B is a diagram showing a cross-section of the electrostatic capacitance element that is the example of the third embodiment of the present disclosure, that is made using the eight green sheets, and in which the seven capacitors are connected in series.

FIG. 39C is a diagram showing an equivalent circuit of the electrostatic capacitance element that is the example of the third embodiment of the present disclosure, that is made using the eight green sheets, and in which the seven capacitors are connected in series.

FIG. 40E is a diagram showing an example of a green sheet that is used in the example of the third embodiment of the present disclosure shown in FIG. 39 and that is made by reversing the basic-pattern green sheet shown in FIG. 24.

FIG. 40F is a diagram showing an example of a green sheet that is used in the example of the third embodiment of the present disclosure shown in FIG. 39 and that is made by reversing a 90°-rotated green sheet in which the basic pattern shown in FIG. 24 is rotated by 90°.

FIG. 40G is a diagram showing an example of a green sheet that is used in the example of the third embodiment of the present disclosure shown in FIG. 39 and that is made by reversing a 180°-rotated green sheet in which the basic pattern shown in FIG. 24 is rotated by 180°.

FIG. 40H is a diagram showing an example of a green sheet that is used in the example of the third embodiment of the present disclosure shown in FIG. 39 and that is made by reversing a 270°-rotated green sheet in which the basic pattern shown in FIG. 24 is rotated by 270° (−90°).

FIG. 41 is a diagram for explaining an outline of a production method of the electrostatic capacitance element shown in FIG. 39.

FIG. 42 is a process diagram showing a procedure of the production method of the electrostatic capacitance element shown in FIG. 39.

### DESCRIPTION OF EMBODIMENTS

Hereinafter, production methods of capacitance elements according to embodiments of the present disclosure will be described with reference to the drawings. The embodiments of the present disclosure will be described in the following order. Here, the present disclosure is not limited to the following examples.

1. A general method of production methods of electrostatic capacitance elements (FIGS. 1 to 9)
2. A production method of an electrostatic capacitance element according to an example of a first embodiment of the present disclosure (FIGS. 10 to 13)

2-1 First modification (FIGS. 14 to 17)

2-2 Second modification (FIGS. 18 to 22)

3. A production method of an electrostatic capacitance element according to an example of a second embodiment of the present disclosure (FIGS. 23 to 26)

3-1 First modification (FIGS. 27 to 29)

3-2 Second modification (FIGS. 30 to 32)

3-3 Third modification (FIGS. 33 to 35)

3-4 Fourth modification (FIGS. 36 to 38)

4. A production method of an electrostatic capacitance element according to an example of a third embodiment of the present disclosure (FIGS. 39 to 42)

### 1. A General Method of Production Methods of Electrostatic Capacitance Elements

Before describing a production method of an electrostatic capacitance element according to an example of a first embodiment of the present disclosure, first, a conventional production method of an electrostatic capacitance element that is generally performed will be described with reference to FIGS. 1 to 9, as a comparative example to the production method of the electrostatic capacitance element according to the example of the embodiment.

FIG. 1A illustrates an external view showing an external appearance of a generally-used electrostatic capacitance element in which plural capacitors are connected in parallel. FIG. 1B illustrates a cross-section view taken from dotted line X-X′. FIG. 1C illustrates an equivalent circuit of this electrostatic capacitance element 10.

The electrostatic capacitance element 10 is constituted by an electrostatic capacitance element body 11 and external electrodes 12a, 12b. The electrostatic capacitance element body 11 is formed by applying a paste-form conductor 13 for forming an electrode on a dielectric sheet 14. Plural (in FIG. 1B, eight) green sheets, each of which includes the dielectric sheet 14 and the conductor 13 with a predetermined electrode pattern formed on the dielectric sheet 14, are laminated, and thereby the electrostatic capacitance element in which seven capacitors are connected in parallel is made. Although not shown in FIG. 1, typically, a sheet (white sheet) that includes only the dielectric sheet 14 with the conductor 13 being not applied, is provided for reinforcement on the upper part and lower part of the laminated green sheets.

FIG. 2 illustrate two green sheets (hereinafter, abbreviated to merely “GS”, in some cases) to be used in FIG. 1. FIG. 2A shows a green sheet with a basic pattern, which is a sheet in which a conductor 13a is applied and compression-bonded on the dielectric 14. The conductor 13a is connected with the external electrode 12a shown in FIG. 1A. FIG. 2B shows a green sheet in which the basic-pattern GS in FIG. 2A is rotated by 180°, and a conductor 13b on this green sheet is connected with the external electrode 12b in FIG. 1A.

FIG. 3 is a diagram for explaining an outline of a production method of the electrostatic capacitance element in FIG. 1. As understood by seeing FIG. 3, four pieces of the basic-pattern GSs 15a shown in FIG. 2A and four pieces of the 180°-rotated GSs 15b shown in FIG. 2B are alternately arrayed in the vertical direction. In addition, three pieces of the sheets (white sheets) 17a, 17b including only the dielectric are laminated on each of the upper part and lower part of the green sheets. These white sheets are used for reinforcement of the electrostatic capacitance element, and therefore, the necessary number is appropriately determined in consideration of the thickness and plane size required for the electrostatic capacitance element.

Here, in the method in which the basic-pattern GS and the 180°-rotated basic-pattern GS are alternately laminated, as for the relationship between the number N (=1, 2, 3 . . . ) of the kinds of green sheets and the number K of capacitors as unit elements that are connected in series, Expression (1) holds.

K=2N−1 (1)

FIG. 1 show a case of N=1, K=1.

FIG. 4A illustrates an external view of an electrostatic capacitance element in which two capacitors made using one more different pattern besides the basic pattern are connected in series. FIG. 4B illustrates a cross-section view taken from dotted line X-X′. FIG. 4C illustrates an equivalent circuit thereof.

As shown in FIG. 4A and FIG. 4C, in the electrostatic capacitance element 20 shown in FIG. 4, two capacitors are connected in series, and therefore, three external electrodes 22a to 22c are formed on an electrostatic capacitance element body 21. As described later in FIG. 5, the electrostatic capacitance element body 21 includes three green sheets each of which is constituted by a dielectric sheet 24 and a conductor 23 applied and compression-bonded on this dielectric sheet.

FIG. 5 illustrate the three green sheets that include different conductors 23a to 23c to be connected with the different external electrodes 22a to 22c. As shown in FIGS. 5A to C, the electrostatic capacitance element body 21 in FIG. 4 has a basic-pattern GS 25a, a 180°-rotated basic-pattern GS 25b that is made by rotating the basic-pattern GS by 180°, and a second-pattern GS 25c that is produced separately from the basic pattern. The second-pattern GS 25c is line-symmetric to the basic-pattern GS 25a with respect to the longitudinal center line. The basic-pattern GS 25a has the conductor 23a, and is connected with the external electrode 22a. The 180°-rotated basic-pattern GS 25b has the conductor 23b, and is connected with the external electrode 22b. The second-pattern GS 25c has the conductor 23c, and is connected with the external electrode 22c.

FIG. 6 is a diagram showing an example of a way to stack the three green sheets when producing the electrostatic capacitance element body 21 shown in FIG. 4. As shown in FIG. 6, the 180°-rotated basic-pattern GS 25b is provided on the basic-pattern GS 25a, and further, the second-pattern GS 25c is laminated on the 180°-rotated basic-pattern GS 25b. Here, the dielectric sheet 24b (see FIG. 5) between the conductor (electrode) 23a of the basic-pattern GS 25a and the conductor 23b of the 180°-rotated basic-pattern GS 25b constitutes a first capacitor 26a, and the dielectric sheet 24c (see FIG. 5) between the conductor 23b of the 180°-rotated basic-pattern GS 25b and the conductor 23c of the second-pattern GS 25c constitutes a second capacitor 26b (see the equivalent circuit in FIG. 4C). Then, white sheets 27a, 27b are laminated on the upper part and lower part of the three laminated green sheets, and the electrostatic capacitance element 20 is made by performing compression-bonding and baking treatments of the whole.

Here, as the compression-bonding treatment, a method of sealing the laminate in a vinyl bag and applying a hydrostatic pressure is possible. To the laminate, which typically has a plate shape, the pressure is applied in the width direction and the long direction other than the thickness direction. However, since the area in the thickness direction (the laminating direction of the plate surfaces) is larger than those in the width direction and the long direction, the compression-bonding of the laminate is performed by the force applied in the thickness direction (the laminating direction).

The baking treatment of the laminate is performed after the compression-bonding. In the baking treatment, typically, the temperature is raised in two steps. That is, in the first step, for eliminating organic substances in the dielectric and the internal electrode paste, the baking treatment is performed at a relatively low temperature (approximately 400° C. that is the thermal decomposition temperature of the organic substances). In the second step, for the melting (or the semi-melting) of the metal for forming the internal electrode and for the sintering of inorganic substances composing the dielectric, the baking is performed at a high temperature of approximately 1300° C. This temperature switching is not always performed in two steps (two temperatures), and the profile of the temperature change is appropriately devised as necessary.

FIG. 7A illustrates an external view of an electrostatic capacitance element 30 in which three capacitors are connected in series. FIG. 7B illustrates an X-X′ cross-section view. FIG. 7C illustrates an equivalent circuit thereof.

As shown in FIG. 7C, the electrostatic capacitance element 30, in which three capacitors 36a to 36c are connected in series, has an electrostatic capacitance element body 31 and four external electrodes 32a to 32d. The electrostatic capacitance element body 31 includes four green sheets each of which includes a dielectric sheet 34 and a conductor 33 applied and compression-bonded on this dielectric sheet 34.

The four green sheets used in production of the electrostatic capacitance element 30 include a fourth green sheet shown in FIG. 8, other than the three kinds of green sheets described in FIG. 5. The green sheet shown in FIG. 8 is a 180°-rotated second-pattern GS 35d in which the second-pattern GS 25c in FIG. 5C is rotated by 180°. This fourth green sheet 35d is constituted by a dielectric 34d and a conductor 33d, and is connected with the external electrode 32d. In the following description, the same green sheets as the green sheets in FIG. 5A to C are described as the GS 35a, GS 35b and GS 35c, which are matched with the reference character of the 180°-rotated second-pattern GS 35d.

FIG. 9 is a diagram for explaining an outline of a production method of the electrostatic capacitance element body 31 in FIG. 7. As shown in FIG. 9, the 180°-rotated basic-pattern GS 35b having a conductor 33b is stacked on the basic-pattern GS 35a having a conductor 33a. Then, the second-pattern GS 35c having a conductor 33c is stacked on the 180°-rotated basic-pattern GS 35b, and further, the 180°-rotated second-pattern GS 35d shown in FIG. 8 is laminated thereon. Here, the dielectric sheet 34b between the conductor 33a of the basic-pattern GS 35a and the conductor 33b of the 180°-rotated basic-pattern GS 35b constitutes a first capacitor 36a, and the dielectric sheet 34c between the conductor 33b of the 180°-rotated basic-pattern GS 35b and the conductor 33c of the second-pattern GS 35c constitutes a second capacitor 36b. Furthermore, the dielectric sheet 34d between the conductor 33c of the second-pattern GS 35c and the conductor electrode 33d of the 180°-rotated second-pattern GS 35d constitutes a third capacitor 36c (see the equivalent circuit in FIG. 7C).

Plural reinforcement white sheets 37a are laminated on the upper part of the 180°-rotated second-pattern GS 35d arranged at the uppermost, and similarly, plural reinforcement white sheets 37b are laminated on the lower part of the basic-pattern GS 35a arranged at the lowermost. The four green sheets and the white sheets arranged on the upper and lower parts are compression-bonded and further are baked so that the electrostatic capacitance element 30 is made. In the production method, also, the “K=2N−1”, which is the above-described Expression (1), is applied. Here, N=2 results in K=3, and three capacitors as unit elements are connected in series.

### 2. A Production Method of an Electrostatic Capacitance Element According to an Example of a First Embodiment of the Present Disclosure

FIG. 10A illustrates an external view of an electrostatic capacitance element 40 that is produced by a production method of an electrostatic capacitance element according to an example of a first embodiment of the present disclosure and in which two capacitors are connected in series. FIG. 10B illustrates a cross-section view taken from dotted line X-X′. FIG. 10C illustrates an equivalent circuit thereof.

The electrostatic capacitance element 40 has the same configuration as the electrostatic capacitance element 20 shown in FIG. 4, except the difference in the making method of the third green sheet. However, for distinction from the conventional electrostatic capacitance element 20 shown in FIG. 4, 40s-numbers are put in FIG. 10.

As shown in FIG. 10C, the electrostatic capacitance element 40 shown in FIG. 4 is an electrostatic capacitance element in which two capacitors 46a, 46b are connected in series, and has an electrostatic capacitance element body 41 and three external electrodes 42a to 42c. The electrostatic capacitance element body 41 is constituted by three green sheets each of which includes a dielectric sheet 44 and a conductor 43 applied and compression-bonded on this dielectric sheet 44.

Here, in the case where three sheets of a basic-pattern green sheet, a 180°-rotated basic-pattern green sheet and a reversed basic-pattern green sheet made by reversing them are laminated in random order, the following holds,

K=4N−1 (2)

where N (=1, 2, 3 . . . ) represents the number of the kinds of green sheets, and K represents the number of capacitors as unit elements that are connected in series. This Expression (2) results in N=1, K=3, and the maximum number of capacitors as unit elements that are connected in series is 3 (described later in FIG. 14). In FIG. 10, two capacitors are connected in series.

Similarly to the electrostatic capacitance element 20 in FIG. 5, the electrostatic capacitance element 40 shown in FIG. 10 includes three green sheets. That is, as shown in FIGS. 11A to C, the electrostatic capacitance element body 41 has a basic-pattern GS 45a, a 180°-rotated basic-pattern GS 45b in which the basic-pattern GS 45a is rotated by 180°, and a reversed basic-pattern GS 45c that is made by reversing the basic pattern. The basic-pattern GS 45a has a conductor 43a, and is connected with an external electrode 42a. The 180°-rotated basic-pattern GS 45b has a conductor 43b, and is connected with an external electrode 42b. The reversed basic-pattern GS 45c has a conductor 43c, and is connected with an external electrode 42c. Here, for distinguishing a green sheet (GS) with a basic pattern or a green sheet (GS) with a pattern in which it is rotated from a green sheet (GS) made by reversing them, as for the green sheet (GS) made by reversing them, the conductor part is shown as a dotted line throughout all the drawings (for example, see FIG. 11C).

FIG. 12 illustrates an example of a way to stack the three green sheets shown in FIG. 11 when producing the electrostatic capacitance element body 41 shown in FIG. 10. As shown in FIG. 12, the 180°-rotated basic-pattern GS 45b is arranged on the upper part of the basic-pattern GS 45a, and further, the reversed basic-pattern GS 45c is arranged on the upper part of the 180°-rotated basic-pattern GS 45b by an intermediary of one white sheet 47c. Here, the dielectric sheet 44b between the conductor 43a of the basic-pattern GS 45a and the conductor 43b of the 180°-rotated basic-pattern GS 45b constitutes a first capacitor 46a, and the white sheet 47c interposed between the conductor 43b of the 180°-rotated basic-pattern GS 45b and the conductor 43c of the reversed basic-pattern GS 45c constitutes a second capacitor 46b (see the equivalent circuit in FIG. 10C).

FIG. 13 is a process diagram showing a production method by the green sheet stacking shown in FIG. 12 on a step-by-step basis for each process. First, dielectric sheets 44 composed of an intended dielectric material are prepared for configuring dielectric layers of the electrostatic capacitance element body 41. Then, for applying a basic-pattern conductor, which is an electrode, on the dielectric sheet 44, a basic-pattern mask (not shown in the figure) in which a region corresponding to a conductor formation region is opened, is prepared (step S11).

In making of the above-described dielectric sheet 44, typically, a dielectric paste in which a dielectric composed of inorganic substance particles is mixed with an organic substance binder that is an adhesive, is made. Then, this dielectric paste is applied on a PET (polyethylene terephthalate) film in an intended thickness, and thereby a dielectric sheet united with the PET is formed. In formation of an electrode on the dielectric sheet, an organic substance binder (adhesive) is added in a conductor composed of metal particles and they are mixed well, and thereby, a conductor (electrode) paste is made. Then, this conductor (electrode) paste is applied on the dielectric sheet united with the PET through a screen-printing mask, and thereby, a conductor sheet is formed.

To explain concretely, as the material of the dielectric sheet 44, for example, a ferroelectric material composed of an ionic crystal material, which electrically polarizes by the atom displacement of positive ions and negative ions, is used. When two predetermined chemical elements are A and B, this ferroelectric material to bring about the ionic polarization is generally represented as chemical formula ABO₃ (O represents oxygen element). Examples of such a ferroelectric material include barium titanate (BaTiO₃), potassium niobate (KNbO₃), lead titanate (PbTiO₃) and the like. Also, PZT (lead zirconate titanate), which is a mixture of lead titanate (PbTiO₃) and lead zirconate (PbZrO₃), may be used as the material of the dielectric sheet 44.

Also, a ferroelectric material to bring about an electronic polarization may be used as the material for forming the dielectric sheet 44. This ferroelectric material brings about an electronic polarization causing a division into a positive-charge-biased part and a negative-charge-biased part. Examples of such a material include a rare-earth iron oxide that forms the polarization and exhibits a ferroelectric property by the formation of a charge plane of Fe²⁺ and a charge plane of Fe³⁺. Here, it is known that materials represented as molecular formula (RE).(TM)₂.O₄ (O: oxygen element), where RE represents a rare-earth element and TM represents an iron-group element, have a high dielectric constant. Examples of the rare-earth element include Y, Er, Yb and Lu (specially, Y and a heavy rare-earth element), and examples of the iron-group element include Fe, Co and Ni (specially, Fe). As the rare-earth iron oxide (RE).(TM)₂.O₄, for example, ErFe₂O₄, LuFe₂O₄, YPe₂O₄ and the like are used.

Next, an applying and compression-bonding of a conductive film on the dielectric sheet is performed using the dielectric sheet and electrode-formation mask prepared in step S11 (step S12). Here, the applying of the conductive film is performed as follows. That is, a conductive paste that is a paste made from metal powder such as Pt, Pb, Pb/Ag, Ni or Ni alloy, is prepared, and then this conductive paste is printed (for example, by silk-printing or the like) on the dielectric sheet 44 through the mask prepared in step S11. Thereby, the basic-pattern GS 45a in which the conductor electrode 43a with the basic pattern is formed on one surface of the dielectric sheet 44 is obtained. Next, the 180°-rotated basic-pattern GS 45b is obtained by rotating the obtained basic-pattern GS 45a by 180° (step S13), and subsequently, the reversed basic-pattern GS 45c is obtained by reversing the basic-pattern GS 45a (step S14).

The basic-pattern GS 45a made in step S12 and the 180°-rotated basic-pattern GS 45b made in step S13 are stacked (step S15), and the white sheet 47c is stacked thereon (step S16). Then, the reversed basic-pattern GS 45c made in step S14 is arranged on this white sheet 47c so that a laminate is made (step S17). Next, a necessary number of reinforcement white sheets 45a, 45b are stacked and laminated on each of the upper part and lower part of the laminate made in step S17, and then, this undergoes compression-bonding and baking treatments to be united (step S18). Finally, the external electrodes 42a to 42c are added so that the electrostatic capacitance element 40 is completed (step S19). Here, typically, the external electrodes 42a to 42c are formed by mixing metal fine particles as a base with a polymeric material composed of a solvent and a binder, so as to make a paste, and then by printing (applying) and baking this.

### [2-1 First Modification]

Next, a first modification of the production method of the electrostatic capacitance element according to the example of the first embodiment of the present disclosure will be described with reference to FIG. 14 to FIG. 17.

FIG. 14A illustrates an external view of an electrostatic capacitance element 50 in which three capacitors 56a to 56c are connected in series. FIG. 14B illustrates a cross-section view taken from dotted line X-X′. FIG. 14C illustrates an equivalent circuit thereof. The difference from the electrostatic capacitance element 40 in FIG. 10 is that, for connecting one more capacitor in series, an extra green sheet is necessary compared to the case of the electrostatic capacitance element 40. That is, as shown in FIG. 14B, four green sheets that include conductors 53a to 53d are necessary.

FIG. 15 illustrates the fourth green sheet that is made by rotating the reversed basic-pattern GS shown in FIG. 11 by 180°. This fourth green sheet is a 180°-rotated and reversed basic-pattern GS 55d in which the basic-pattern GS 45a is rotated by 180° and further this is reversed. Although the electrostatic capacitance element 50 in FIG. 14 also uses the green sheets 45a to 45c in FIG. 11, the reference characters of the green sheets are 55a to 55c herein, in accordance with the newly-used green sheet 55d.

FIG. 16 illustrates a state in which white sheets are laminated on the four green sheets in the electrostatic capacitance element 50. As understood from FIG. 16, the dielectric sheet 54b arranged between the conductor 53a of the basic-pattern GS 55a and the conductor 53b of the 180°-rotated basic-pattern GS 55b constitutes a first capacitor 56a shown in the equivalent circuit in FIG. 14C. The dielectric sheet 54c arranged between the conductor 53c of the reversed basic-pattern GS 55c and the conductor 53d of the 180°-rotated and reversed basic-pattern GS 55d constitutes a third capacitor 56c shown in the equivalent circuit in FIG. 14C.

In FIG. 16, a white sheet 57c including only a dielectric on which a conductor is not being compression-bonded is interposed between the 180°-rotated GS 55b and the reversed basic-pattern GS 55c. The conductor 53b of the 180°-rotated basic-pattern GS 55b and the conductor 53c of the reversed basic-pattern GS 55c that sandwich the white sheet 57c, and the white sheet 57c constitute a second capacitor 56b shown in the equivalent circuit in FIG. 14C. Here, white sheets 57a, 57b are laminated for reinforcement, on the upper part and lower part of the four laminated green sheets.

Next, a production process of the electrostatic capacitance element 50 shown in FIG. 14 will be described with reference to a flowchart in FIG. 17. In the flowchart in FIG. 17, the same step signs (steps S11 to S16) are put to the same processes as the flowchart in FIG. 13. They have been already described in FIG. 13, and therefore repetitive descriptions are omitted.

FIG. 17 contains a making process of the 180°-rotated and reversed basic-pattern GS 55d (see FIG. 15) that is newly shown in step S19. Then, a laminate in which the reversed basic-pattern GS 55c and the 180°-rotated and reversed basic-pattern GS 55d are stacked in random order on the white sheet 57c prepared in step S16, is made (step S20).

Subsequently, the laminate made in step S20 is stacked on the upper part of the laminate made in step S15 (step S21). Further, plural reinforcement white sheets 57a, 57b are arranged on the upper part and lower part of the laminate made in step S21, and then compression-bonding and baking treatments are performed (step S22). Finally, the external electrodes 52a to 52d are printed on the laminate treated in step S22, and a baking treatment is performed, and thereby the electrostatic capacitance element 50 is made (step S23).

### [2-2 Second Modification]

Next, a second modification of the production method of the electrostatic capacitance element according to the example of the first embodiment of the present disclosure will be described with reference to FIGS. 18 to 22.

FIG. 18A illustrates an external view of an electrostatic capacitance element 60 in which seven capacitors 66a to 66g are connected in series. FIG. 18B illustrates a cross-section view taken from dotted line X-X′. FIG. 18C illustrates an equivalent circuit thereof.

Since the electrostatic capacitance element 60 in FIG. 18 is an electrostatic capacitance element in which the seven capacitors 66a to 66g are connected in series, eight external electrodes 62a to 62h and eight conductors 63a to 63h are necessary, including terminals for the electrodes between the respective capacitors. That is, eight green sheets 65a to 65h that have two kinds of basic patterns are necessary. Hereinafter, the two kinds of basic patterns are described as a first pattern and a second pattern.

FIG. 19 and FIG. 20 illustrate four green sheets having the first pattern and four green sheets having the second pattern, respectively.

FIG. 19A illustrates a green sheet (GS) 65a that is the basis of the first pattern. This first-pattern GS 65a becomes a 180°-rotated first-pattern GS 65b shown in FIG. 19B when being rotated by 180°, and the first-pattern GS 65a becomes a reversed first-pattern GS 65c shown in FIG. 19C when being reversed. FIG. 19D illustrates a 180°-rotated and reversed first-pattern GS 65d that is made by further reversing the 180°-rotated first-pattern GS 65b in FIG. 19B.

FIG. 20 illustrate the four green sheets 65e to 65h having the second pattern. In the green sheets with the second pattern shown in FIG. 20, the conductor portions constituting the electrodes of the capacitors are roughly the same as the first pattern, and the leading line portions for the connections with the external electrodes are different from the green sheets with the first pattern shown in FIG. 19.

FIG. 20E illustrates a second-pattern GS 65e that is the basis of the second pattern. This second-pattern GS 65e becomes a 180°-rotated second-pattern GS 65f shown in FIG. 20F when being rotated by 180°, and the second-pattern GS 65e becomes a reversed second-pattern GS 65g shown in FIG. 20G when being reversed. Further, FIG. 20H illustrates a 180°-rotated and reversed second-pattern GS 65h that is made by reversing the 180°-rotated second-pattern GS 65f in FIG. 20F.

When matching FIG. 19 and FIG. 20 with FIG. 18, the green sheets 65a to 65d associated with the first pattern shown in FIGS. 19A to D are connected with the external electrodes 62a to 62d shown in FIG. 18A, while the green sheets 65e to 65h associated with the second pattern are connected with the external electrodes 62e to 62h shown in FIG. 18A. The external electrodes 62a to 62h are insulated from each other by the interposition of the dielectrics, and therefore, as shown in FIG. 18C, it is possible to produce the electrostatic capacitance element 60 with a series connection in which external terminals are attached to all the seven capacitors.

FIG. 21 illustrates an outline of a way to stack eight green sheets in production of the electrostatic capacitance element 60 shown in FIG. 18 in which the seven capacitors 66a to 66g are connected in series.

As shown in FIG. 21, four green sheets of the first-pattern GS 65a, the 180°-rotated first-pattern GS 65b, the second-pattern GS 65e and the 180°-rotated second-pattern GS 65f are laminated in random order. A white sheet 67c is arranged on the laminated green sheets, and on this white sheet 67c, four green sheets of the reversed second-pattern GS 65g, the 180°-rotated and reversed second-pattern GS 65h, the 180°-rotated and reversed first-pattern GS 65d and the reversed first-pattern GS 65c are laminated in random order. After the eight green sheets having the two patterns are laminated in such a way, plural white sheets 67a, 67b are stacked and arranged on the upper part and lower part thereof.

The number N of the basic-pattern green sheets (the number of the kinds of the green sheets) used in the production method of the electrostatic capacitance element 60 shown in FIG. 18 to FIG. 21 is “2”. Therefore, the above-described Expression (2), K=4N−1 is applied, and the number K of the capacitors as unit elements that are connected in series is “7”.

FIG. 22 is a process diagram showing a procedure of the production method of the electrostatic capacitance element 60 shown in FIG. 18. Although there are some overlaps with the process diagrams in FIG. 13 and FIG. 17, hereinafter, the whole process will be briefly described from the beginning. First, for making green sheets to be used in production of the electrostatic capacitance element body 61, dielectric sheets 64 composed of an intended dielectric material, and two kinds of masks of the first pattern and the second pattern, by which the conductor electrodes are formed on the dielectric sheets 64, are prepared (step S30).

Next, as described in FIG. 13, a conductive paste that is a paste made from metal powder is prepared, and this conductive paste is applied on the dielectric sheet 64 through the first-pattern mask prepared in step S30. Thereby, the first-pattern GS 65a (FIG. 19A) in which the conductor electrode 63a with the first pattern is formed on one surface of the dielectric sheet 64, is obtained (step S31). Next, the 180°-rotated first-pattern GS 65b (FIG. 19B) is obtained by rotating the obtained first-pattern GS 65a by 180° (step S32), and subsequently, the reversed first-pattern GS 65c (FIG. 19C) is obtained by reversing the first-pattern GS 65a (step S33). Furthermore, the 180°-rotated and reversed first-pattern GS 65d (FIG. 19D) is obtained by reversing the 180°-rotated first-pattern GS 65b (step S34).

Subsequently, using an intended dielectric sheet 64 and the mask for forming the second pattern that is prepared in step S30, a conductive paste that is a paste made from metal powder is applied on this dielectric sheet 64 through the second-pattern mask. Thereby, the second-pattern GS 65e (FIG. 20E) in which the conductor electrode 63e with the second pattern is formed on one surface of the dielectric sheet 64, is obtained (step S35). The 180°-rotated second-pattern GS 65f (FIG. 20F) is obtained by rotating the second-pattern GS 65e by 180° (step S36), and, similarly to the case of the first pattern, the reversed second-pattern GS 65g (FIG. 20G) and the 180°-rotated and reversed second-pattern GS 65h (FIG. 20H) are obtained (steps S37, S38).

Next, a laminate in which the first-pattern GS 65a (FIG. 19A), the 180°-rotated first-pattern GS 65b (FIG. 19B), the second-pattern GS 65e (FIG. 20E) and the 180°-rotated second-pattern GS 65f (FIG. 20F) are stacked in random order, is made (step S39). Furthermore, a white sheet 67c including only a dielectric on which a conductor pattern is not being printed is prepared, and a laminate in which the reversed first-pattern GS 65c (FIG. 19C), the 180°-rotated and reversed first-pattern GS 65d (FIG. 19D), the reversed second-pattern GS 65g (FIG. 20G) and the 180°-rotated and reversed second-pattern GS 65h (FIG. 20H) are stacked on the white sheet 67c in random order, is made (step S40).

Then, the laminate made in step S40 is stacked on the laminate made in step S39. Further, plural white sheets 67a, 67b are stacked on the upper part and lower part of the laminate, and then compression-bonding and baking treatments are performed (step S41). Finally, the external electrodes 62a to 62h are printed on the laminate made in step S41 and a baking is performed, and thereby the electrostatic capacitance element 60 shown in FIG. 18, in which the seven capacitors 66a to 66g are connected in series, is obtained (step S42).

### 3. A Production Method of an Electrostatic Capacitance Element According to an Example of a Second Embodiment of the Present Disclosure

Next, an electrostatic capacitance element according to an example of a second embodiment of the present disclosure and a production method thereof will be described with reference to FIGS. 23 to 26.

FIG. 23A illustrates an external view of an electrostatic capacitance element 70 in which three capacitors 76a to 76c are connected in series. FIG. 23B illustrates a cross-section view taken from dotted line X-X′. FIG. 23C illustrates an equivalent circuit thereof. As understood from the external view, in this example of the second embodiment, external electrodes 72a to 72d are present at roughly the same positions on the four side surfaces of an electrostatic capacitance element body 71 having a rectangular parallelepiped shape.

These external electrodes 72a to 72d are connected with conductors 73a to 73d shown in the cross-section view, resulting in a connection relation of three capacitors 76a to 76c and the external electrodes 72a to 72d shown in the equivalent circuit.

FIGS. 24A to D illustrate four green sheets 75a to 75d having a basic pattern. In FIG. 24, the areas of capacitor-electrode formation portions of the conductors 73a to 73d are small compared to the areas of the dielectrics 74a to 74d. The area sizes of these conductors 73a to 73d can be arbitrarily determined depending on the purpose of use of the electrostatic capacitance element 70. For example, in the case where the electrostatic capacitance element 70 is used while being mounted on a communication card, it is known that it is more effective to lessen the areas of the conductors 73a to 73d compared to the areas of the dielectrics 74a to 74d, as shown in FIGS. 24A to D.

As understood by seeing FIGS. 24A to D, in the B, C and D, a basic-pattern GS 75a shown in the A is rotated by 90°, 180° and 270°, respectively. Hereinafter, these three green sheets (GSs) are referred to as a 90°-rotated basic-pattern GS 75b, a 180°-rotated basic-pattern GS 75c and a 270°-rotated basic-pattern GS 75d.

Here, in the case of laminating the basic-pattern GS 75a, the 90°-rotated basic-pattern GS 75b, the 180°-rotated basic-pattern GS 75c and the 270°-rotated basic-pattern GS 75d in random order, as for the relationship between the number N (=1, 2, 3 . . . ) of the kinds of green sheets and the number K of capacitors as unit elements that are connected in series, the following holds.

K=4N−1 (2)

Here, N=1 results in the number of capacitors as unit elements that are connected in series, K=3.

FIG. 25 illustrates an outline of a way to stack the above-described four green sheets (GSs) for producing the electrostatic capacitance element 70 shown in FIG. 23 in which the three capacitors 76a to 76c are connected in series. That is, the basic-pattern GS 75a, the 90°-rotated basic-pattern GS 75b, the 180°-rotated basic-pattern GS 75c and the 270°-rotated basic-pattern GS 75d are stacked in random order, and plural white sheets 77a, 77b are laminated on the upper part and lower part thereof.

FIG. 26 is a process diagram showing a procedure of a production method of the electrostatic capacitance element 70 shown in FIG. 23. A process of preparing dielectric sheets and a mask for applying a conductor film in step S50 and a making of the basic-pattern GS 75a (FIG. 24A) in step S51 are the same as the method described previously.

Next, the 90°-rotated basic-pattern GS 75b (FIG. 24B) is made by rotating the basic-pattern GS 75a made in step S51 by 90° (step S52). Subsequently, the 180°-rotated basic-pattern GS 75c (FIG. 24C) is made by rotating the basic-pattern GS 75a by 180° (step S53), and further, the 270°-rotated basic-pattern GS 75d (FIG. 24D) is made by rotating it by 270° (step S54).

Then, a laminate in which the four green sheets (GSs) made in such a way are stacked in random order, is made (step S55). Further, plural white sheets 77a, 77b are laminated on the upper part and lower part of this laminate, and then compression-bonding and baking treatments are performed (step S56). Finally, the external electrodes 72a to 72d are printed on the laminate made in step S56 and a baking treatment is performed, and thereby, the production of the electrostatic capacitance element 70 finishes (step S57).

### [3-1 First Modification]

A first modification of the electrostatic capacitance element according to the example of the second embodiment of the present disclosure and a production method thereof will be described with reference to FIGS. 27 to 29.

FIG. 27A illustrates an external view of an electrostatic capacitance element 80 in which three sets of two parallelly-connected capacitors 86a, 86b, 86c are individually connected in series. FIG. 27B illustrates a cross-section view taken from dotted line X-X′. FIG. 27C illustrates an equivalent circuit thereof FIG. 27D illustrates an internal circuit. External electrodes 82a to 82d in this first modification are the same as the external electrodes 72a to 72d in FIG. 23.

These external electrodes 82a to 82d are connected with conductors 83a to 83d shown in the cross-section view. As shown in FIG. 28, seven green sheets of one basic-pattern GS 85a, two 90°-rotated basic-pattern GSs 85b, two 180°-rotated basic-pattern GSs 85c and two 270°-rotated basic-pattern GSs 85d are prepared, as green sheets (GSs) made of the conductors 83a to 83d and dielectric sheets 84a to 84d.

Next, an example of the arrangement relation of the above-described seven green sheets will be described with reference to FIG. 28. First, the basic-pattern GS 85a is placed at the center. On the upper part and lower part thereof, the 180°-rotated basic-pattern GS 85c, the 90°-rotated basic-pattern GS 85b and the 270°-rotated basic-pattern GS 85c are stacked and arranged in this order. Thereby, three green sheets are laminated on the upper side and lower side of the one basic-pattern GS 85a. Further, plural white sheets 87a, 87b are laminated on the upper part and lower part of the seven green sheets stacked in such a way.

By laminating the seven green sheets in such a way, the two capacitors 86a are made of the one basic-pattern GS 75a and the two 180°-rotated basic-pattern GSs 85c, and the two capacitors 86b are made of the two 180°-rotated basic-pattern GSs 85c and the two 90°-rotated basic-pattern GSs 85b. In addition, the two capacitors 86c are made of the two 90°-rotated basic-pattern GSs 85b and the two 270°-rotated basic-pattern GSs 85d. Then, by connecting the conductors 83a to 83d of the green sheets 85a to 85d to the external electrodes 82a to 82d, the electrostatic capacitance element 80 in which the six capacitors (the numbers of 86a, 86b and 86c are two, respectively) are laminated as shown in the internal circuit, is obtained.

FIG. 29 is a process diagram showing a concrete production process of the electrostatic capacitance element 80. Step S50 to step S54 are the same as the production process of the electrostatic capacitance element 70 shown in FIG. 26, and therefore, the descriptions are omitted.

After the four green sheet, which are made in steps S51 to S54, are made, the 180°-rotated basic-pattern GS 85c, the 90°-rotated basic-pattern GS 85b and the 270°-rotated basic-pattern GS 85d are stacked in this order on the upper part of the basic-pattern GS 85a so that a laminate is made (step S58). Then, on the lower part of the laminate made in step S58, the 180°-rotated basic-pattern GS 85c, the 90°-rotated basic-pattern GS 85b and the 270°-rotated basic-pattern GS 85d are stacked in this order to become a laminate (step S59). That is, as shown in FIG. 28, the laminate, in which the basic-pattern GS 85a is a common green sheet and on the upper and lower parts thereof, the 180°-rotated basic-pattern GS 85c, the 90°-rotated basic-pattern GS 85b and the 270°-rotated basic-pattern GS 85d are arranged in order so that the seven green sheets are laminated, is obtained.

Subsequently, the plural white sheets 87a, 87b are stacked on the upper part and lower part of the laminate of the seven green sheets made in step S59, and then compression-bonding and baking treatments are performed (step S60). Finally, the external electrodes 82a to 82d are printed and a baking treatment is performed, and thereby, the production process of the electrostatic capacitance element 80 finishes (step S61).

### [3-2 Second Modification]

Next, a second modification of the electrostatic capacitance element according to the example of the second embodiment of the present disclosure and a production method thereof will be described with reference to FIGS. 30 to 32.

The second modification shown in FIG. 30 is different from the first modification shown in FIG. 27, only in the cross-section view taken from X-X′. That is, the electrostatic capacitance element 80 shown in FIG. 27 has the seven conductors (the number of 83a is one, and the numbers of 83b to 83d are two, respectively) as shown in FIG. 27B while eight conductors (the numbers of 83a to 83d are two, respectively) are provided in an electrostatic capacitance element 80A in FIG. 30.

FIG. 31 illustrates an example of the arrangement relation of eight green sheets on which the above-described eight conductors are applied. Two basic-pattern GSs 85a are stacked and arranged at the central part. Conductor electrodes 83a of the basic-pattern GSs 85a are electrodes that are connected with an external electrode 82a. Two laminates each of which includes four green sheets are made, by stacking three green sheets of a 180°-rotated basic-pattern GS 85c, a 90°-rotated basic-pattern GS 85b and a 270°-rotated basic-pattern GS 85c, on the upper part and lower part of the basic-pattern GSs 85a. Further, plural white sheets 87a, 87b are stacked and arranged on the upper part and lower part of the two laminates stacked in such a way.

In the case of laminating the eight green sheets in such a way, similarly to the case in FIG. 28, the two capacitors 86a are made of the two basic-pattern GSs 85a and the two 180°-rotated basic-pattern GSs 85c, and the two capacitors 86b are made of the two 180°-rotated basic-pattern GSs 85c and the two 90°-rotated basic-pattern GSs 85b. In addition, the two capacitors 86c are made of the two 90°-rotated basic-pattern GSs 85b and the two 270°-rotated basic-pattern GSs 85d. Thereby, the electrostatic capacitance element 80A in which the six capacitors (the numbers of 86a, 86b and 86c are two, respectively) are laminated as shown in the internal circuit of FIG. 30D, is obtained.

FIG. 32 is a process diagram showing a concrete production process of the electrostatic capacitance element 80A. Step S50 to step S54 are the same as the production process of the electrostatic capacitance element 80 shown in FIG. 28. First, three green sheets of the 180°-rotated basic-pattern GS 85c, the 90°-rotated basic-pattern GS 85b and the 270°-rotated basic-pattern GS 85c are arranged on the upper part of one basic-pattern GS 85a so that a laminate is formed (step S63). Further, three green sheets of the 180°-rotated basic-pattern GS 85c, the 90°-rotated basic-pattern GS 85b and the 270°-rotated basic-pattern GS 85d are arranged on the lower part of another basic-pattern GS 85a so that a laminate is formed (step S64).

Then, the laminates made in steps S63, S64 are stacked (step S65), and further, on the upper part and lower part thereof, the plural white sheets 87a, 87b are laminated, and then compression-bonding and baking treatments are performed (step S66). Finally, the printing and baking treatments of the external electrodes 82a to 82d (see FIG. 30A) are performed on the laminate made in step S66, and the production of the electrostatic capacitance element 80A finishes (step S67).

### [3-3 Third Modification]

Next, a third modification of the electrostatic capacitance element according to the example of the second embodiment of the present disclosure and a production method thereof will be described with reference to FIGS. 33 to 35.

A third modification (an electrostatic capacitance element 80B) shown in FIG. 33 is different from the first modification shown in FIG. 27 and the second modification in FIG. 30, in that three sets of three parallel capacitors 86a, 86b, 86c are connected in series as shown in the internal circuit. Thereby, in the third modification, as shown in FIG. 33B, ten conductors (the numbers of 83a, 83d are two, respectively, and the numbers of 83b, 83c are three, respectively) for forming electrodes are provided.

FIG. 34 illustrates a way to stack the ten green sheets (GSs) constituting the electrostatic capacitance element 80B in FIG. 33. A total of ten green sheets, which are two basic-pattern GSs 85a, two 270°-rotated basic-pattern GSs 85d, three 90°-rotated basic-pattern GSs 85b and three 180°-rotated basic-pattern GSs 85c, are used. Then, two laminates in which green sheets of the 180°-rotated basic-pattern GS 85c, the 90°-rotated basic-pattern GS 85b and the 270°-rotated basic-pattern GS 85c are stacked and arranged in this order on the upper parts of the two basic-pattern GSs 85a, are made.

When the 180°-rotated basic-pattern GS 85c and the 90°-rotated basic-pattern GS 85b are interposed between the two same laminates, the basic-pattern GS 85a of the laminate arranged in the upper part and the 270°-rotated basic-pattern GS 85d of the laminate arranged in the lower part are used in common, and thereby, one more laminate, which has the basic-pattern GS 85a, the 180°-rotated basic-pattern GS 85c, the 90°-rotated basic-pattern GS 85b and the rotated basic-pattern GS 85c, is made. In each of these three laminates that are laminated in such a way, the capacitors 86a to 86c are connected in series, and when the green sheets constituting these three laminates are connected to the external electrodes 82a to 82d, a capacitor circuit configuration shown in the internal circuit of FIG. 33D, in which three sets of three parallelly-connected capacitors 86a to 86c are connected in series, is realized. Further, similarly to FIG. 31, plural white sheets 87a, 87b are laminated on the upper part and lower part of the ten green sheets stacked in such a way.

To explain concretely, the three capacitors 86a are made of the two basic-pattern GSs 85a and the three 180°-rotated basic-pattern GSs 85c, and the three capacitors 86b are made of the three 180°-rotated basic-pattern GSs 85c and the three 90°-rotated basic-pattern GSs 85b. In addition, the three capacitors 86c are made of the three 90°-rotated basic-pattern GSs 85b and the two 270°-rotated basic-pattern GSs 85d. Thereby, the electrostatic capacitance element 80B, in which three sets of three parallelly-connected capacitors are connected in series as shown in the internal circuit of FIG. 33D so that the nine capacitors (the numbers of 86a, 86b and 86c are three, respectively) are laminated, is obtained.

FIG. 35 is a process diagram showing a concrete production process of the electrostatic capacitance element 80B. Step S50 to step S54 are the same as the production process of the electrostatic capacitance element 80A shown in FIG. 30.

After the process of step S54 finishes, two laminates in each of which the 180°-rotated basic-pattern GS 85c, the 90°-rotated basic-pattern GS 85b and the 270°-rotated basic-pattern GS 85d are laminated on the upper part of the basic-pattern GS 85a, are made (step S68). Then, a laminate of the 90°-rotated basic-pattern GS 85b and the 180°-rotated basic-pattern GS 85c is interposed between the two laminates made in step S68 (step S69).

Then, the plural white sheets 87a, 87b are laminated on the upper part and lower part of the laminate made in step S69, and then compression-bonding and baking treatments are performed (step S70). Finally, the printing and baking treatments of the external electrodes 82a to 82d (see FIG. 33A) are performed, and thereby the electrostatic capacitance element 80B is produced (step S71).

### [3-4 Fourth Modification]

Next, a fourth modification of the electrostatic capacitance element according to the example of the second embodiment of the present disclosure and a production method thereof will be described with reference to FIGS. 36 to 38.

An electrostatic capacitance element 80C according to a fourth modification shown in FIG. 36 is the same as the electrostatic capacitance element 80B shown in FIG. 33 with respect to both the external view and the internal circuit, and the difference is only the number of conductor electrodes 83a to 83d shown in the X-X′ cross-section view (B). That is, in FIG. 33B, as described above, the ten conductor electrodes (the numbers of 83a and 83d are two, respectively, and the numbers of 83b and 83c are three, respectively) are included, while in FIG. 36B, twelve conductor electrodes (the numbers of 83a to 83d are three, respectively) are included.

FIG. 37 illustrates a way to stack twelve green sheets (GSs) constituting the electrostatic capacitance element 80C in FIG. 36. As shown in FIG. 37, two laminates in each of which three green sheets of a 180°-rotated basic-pattern GS 85c, a 90°-rotated basic-pattern GS 85b and a 270°-rotated basic-pattern GS 85c are stacked and arranged in this order on the upper part of a basic-pattern GS 85a, are made. Also, one laminate in which a 180°-rotated basic-pattern GS 85c, a 90°-rotated basic-pattern GS 85b and a 270°-rotated basic-pattern GS 85d are laminated on the lower part of another basic-pattern GS 85a, is made. Then, these three laminates are constructed such that they are stacked and further plural white sheets 87a, 87b are stacked on the upper part and lower part thereof.

In each of these three laminates, the three capacitors 86a to 86c shown in the internal circuit of FIG. 36D are connected in series, and they are connected with the external electrodes 82a to 82d. Thereby, the capacitors corresponding to the respective laminates are connected in parallel. As a result, the electrostatic capacitance element 80C having the three-parallel and three-series capacitors shown in the internal circuit is made.

The difference between FIG. 37 and FIG. 34 is that the two basic-pattern GSs 85a and two 270°-rotated basic-pattern GSs 85d are used in FIG. 34 while, for both of them, three green sheets are used in FIG. 37. Therefore, in FIG. 37, the three capacitors 86a are made of the three basic-pattern GSs 85a and the three 180°-rotated basic-pattern GSs 85c, and the three capacitors 86b are made of the three 180°-rotated basic-pattern GSs 85c and the three 90°-rotated basic-pattern GSs 85b. In addition, the three capacitors 86c are made of the three 90°-rotated basic-pattern GSs 85b and the three 270°-rotated basic-pattern GSs 85d. Thereby, the electrostatic capacitance element 80C, in which three sets of three parallelly-connected capacitors are connected in series as shown in the internal circuit of FIG. 36D so that the nine capacitors (the numbers of 86a, 86b and 86c are three, respectively) are laminated, is obtained.

FIG. 38 is a process diagram showing a concrete production process of the electrostatic capacitance element 80C. Step S50 to step S54 are the same as the production processes of the electrostatic capacitance elements 80, 80A, 80B according to the first to third modifications (see FIG. 29, FIG. 32 and FIG. 35).

Thereafter, two basic-pattern GSs 85a, which are made in step S51, are prepared, and then, two laminates in which the 180°-rotated basic-pattern GS 85c, the 90°-rotated basic-pattern GS 85b and the rotated basic-pattern GS 85d are stacked on the upper parts of the basic-pattern GSs 85a, are made (step S72). Further, another basic-pattern GS 85a is prepared, and then, one laminate in which the 180°-rotated basic-pattern GS 85c, the 90°-rotated basic-pattern GS 85b and the 270°-rotated basic-pattern GS 85d are stacked in order on the lower part of this basic-pattern GS 85a, is made (step S73).

Then, the one laminate made in step S73 is interposed between the two laminates made in step S72 so that a laminate in which the twelve green sheets are laminated is made (step S74). In addition, the plural white sheets 87a, 87b are arranged on the upper part and lower part of the laminate made in step S74, and then compression-bonding and baking treatments are performed (step S75). Finally, the external electrodes 82a to 82d (see FIG. 36A) are printed and a baking treatment is performed, and thereby the electrostatic capacitance element 80C is completed (step S76).

### 4. A Production Method of an Electrostatic Capacitance Element According to an Example of a Third Embodiment of the Present Disclosure

Next, a production method of an electrostatic capacitance element according to an example of a third embodiment of the present disclosure will be described with reference to FIGS. 39 to 42.

FIG. 39A illustrates an external view of an electrostatic capacitance element 90 in which seven capacitors 96a to 96g are connected in series. FIG. 39B illustrates an X-X′ cross-section view. FIG. 39C illustrates an equivalent circuit thereof. As understood from the external view, in this example of the third embodiment, two-arrayed external electrodes 92a to 92h are arranged on the four side surfaces of an electrostatic capacitance element body 91 having a rectangular parallelepiped shape.

These external electrodes 92a to 92h are connected with conductors 93a to 93h shown in the cross-section view, and as a result, the seven capacitors 96a to 96g are connected in series as shown in the equivalent circuit so that the electrostatic capacitance element 90 is obtained.

Of green sheets (see FIG. 39B) that are used in this example of the third embodiment and on which the eight conductors (electrodes) are applied, four green sheets are the same as the green sheets shown previously in FIGS. 24A to D. In FIG. 24, they are shown as the four green sheets 75a to 75d having the basic pattern. In the example of the third embodiment, the same green sheets are shown as green sheets 95a to 95d.

Further, in the electrostatic capacitance element 90 according to the example of the third embodiment, four green sheets 95e to 95h shown in FIGS. 40E to H are used, in addition to the four green sheets shown in FIGS. 24A to D. These green sheets 95e to 95h are green sheets in which the green sheets 75a to 75d (hereinafter, referred to as “95a to 95d”) shown in FIGS. 24A to D are reversed.

That is, for producing the electrostatic capacitance element 90, other than four green sheets of a basic-pattern GS and its rotated (90°-rotated, 180°-rotated and 270°-rotated) green sheets, further four green sheets that are made by reversing these four green sheets are used. As a result, as for the relationship between the number N (=1, 2, 3 . . . ) of the kinds of green sheets and the number K of capacitors as unit elements that are connected in series, the following holds.

K=8N−1 (3)

That is, N=1 results in K=7, and therefore, as shown in the equivalent circuit in FIG. 39C, green sheets having just one kind of basic pattern give a serial connection structure of the seven capacitors as unit elements.

In FIG. 39, since the number of the external electrodes 92a to 92h is eight, the limit of the number of capacitors as unit elements that are connected in series is seven. However, needless to say, if the number of external electrodes is sixteen and the electrode formation pattern N is “2”, an electrostatic capacitance element in which fifteen capacitors as unit elements are connected in series, is obtained.

Hereinafter, the green sheets shown in FIGS. 40E to H are referred to as a reversed basic-pattern GS 95e, a 90°-rotated and reversed basic-pattern GS 95f, a 180°-rotated and reversed basic-pattern GS 95g and a 270°-rotated and reversed basic-pattern GS 95h.

FIG. 41 illustrates an example of a way to stack the above-described eight green sheets (GSs) for producing the electrostatic capacitance element 90 in which the seven capacitors 96a to 96g shown in FIG. 39 are connected in series. That is, the basic-pattern GS 95a, the 90°-rotated basic-pattern GS 95b, the 180°-rotated basic-pattern GS 95c and the 270°-rotated basic-pattern GS 95d are laminated in random order. Then, one white sheet 97c is arranged on this laminated green sheets, and further, on the upper part thereof, the reversed basic-pattern GS 95e, the 90°-rotated and reversed basic-pattern GS 95f, the 180°-rotated and reversed basic-pattern GS 95g and the 270°-rotated and reversed basic-pattern GS 95h are laminated in random order. Then, plural white sheets 97a, 97b for reinforcement are laminated on the upper part and lower part of the eight green sheets laminated in such a way, and compression-bonding and baking treatments of the whole are performed.

FIG. 42 is a process diagram showing a concrete production process of the electrostatic capacitance element 90. Step S50 to step S54 are the same as the process described in the production method of the electrostatic capacitance element 70 according to the example of the second embodiment in FIG. 26. That is, in steps S51 to S54, the basic-pattern GS 95a is made, and thereafter, the 90°-rotated basic-pattern GS 95b in which the basic-pattern GS 95a is rotated by 90°, the 180°-rotated basic-pattern GS 95c in which it is rotated by 180°, and the 270°-rotated basic-pattern GS 95d in which it is rotated by 270°, are made.

Next, the reversed basic-pattern GS 95e that is a green sheet in which the basic-pattern GS 95a is reversed, the 180°-rotated GS and reversed basic-pattern GS 95f in which the 180°-rotated basic-pattern GS 95c is reversed, and the 270°-rotated GS and reversed basic-pattern GS 95h in which the 270°-rotated basic-pattern GS 95d is reversed, are made (steps S80 to S83).

Thereafter, first, from the eight kinds of green sheets made in such a way, the basic-pattern GS 95a is taken, and thereon, the 180°-rotated basic-pattern GS 95c, the 90°-rotated basic-pattern GS 95b and the 270°-rotated basic-pattern GS 95d are stacked in random order so that a laminate is made (step S84). Subsequently, one white sheet 97c is stacked and arranged on the laminate made in step S84 (step S85).

Next, a laminate in which the 270°-rotated and reversed basic-pattern GS 95h, the 90°-rotated and reversed basic-pattern GS 95f, the 180°-rotated and reversed basic-pattern GS 95g and the reversed basic-pattern GS 95e are laminated in random order on the upper part of the white sheet 97c arranged in step S85, is made (step S86). Then, plural white sheets 97a, 97b are arranged on the upper part and lower part of the eight green sheets laminated in such a way, and then compression-bonding and baking treatments are performed (step S87). Finally, the external electrodes 92a to 92h (see FIG. 39A) are printed and a baking treatment is performed, and thereby, the electrostatic capacitance element 90 is produced (step S88).

In the examples of the embodiments of the present disclosure described above, the production methods of the various kinds of electrostatic capacitance elements have been described, in consideration of the number of capacitors and the difference of the connection configurations. However, needless to say, the production method of the electrostatic capacitance element according to the present disclosure is not limited to the examples of the embodiments of the above-described electrostatic capacitance elements, and includes other applications and modifications in the range without departing from the descriptions in the claims. Furthermore, the production methods of the electrostatic capacitance elements disclosed in the specification are mainly intended to laminate green sheets that are made by applying conductive films on dielectric sheets, and as a production method of such a laminate, a wide range of use application is possible, other than an electrostatic capacitance element.

Additionally, the present technology may also be configured as below.

(1)

A production method of an electrostatic capacitance element, including:

preparing a dielectric sheet on which a conductor is not being applied, and a mask that has at least one basic pattern shape for applying the conductor on the dielectric sheet;

making a basic-pattern green sheet by applying the conductor on the dielectric sheet through the mask;

making a rotated basic-pattern green sheet in which the basic-pattern green sheet is rotated;

laminating the basic-pattern green sheet and the rotated basic-pattern green sheet;

making a reversed basic-pattern green sheet by reversing at least one green sheet of the basic-pattern green sheet or the rotated basic-pattern green sheet, the reversed basic-pattern green sheet being different from the basic-pattern green sheet or the rotated basic-pattern green sheet;

laminating the reversed basic-pattern green sheet on a laminate with a dielectric sheet, on which a conductor is not being applied, interposed therebetween, the laminate being resulting from laminating the basic-pattern green sheet and the rotated basic-pattern green sheet; and

performing compression-bonding and baking treatments of a laminate of the basic-pattern green sheet, the rotated basic-pattern green sheet, the dielectric sheet and the reversed basic-pattern green sheet.

(2)

The production method of the electrostatic capacitance element according to (1), further including

laminating a reinforcement dielectric sheet on which a conductor is not being applied, on an upper part and a lower part of the laminate of the basic-pattern green sheet, the rotated basic-pattern green sheet, the dielectric sheet and the reversed basic-pattern green sheet.

(3)

The production method of the electrostatic capacitance element according to (2), further including

printing an external electrode on a side surface of the laminate of the basic-pattern green sheet, the rotated basic-pattern green sheet, the dielectric sheet and the reversed basic-pattern green sheet, and then performing a baking treatment.

(4)

The production method of the electrostatic capacitance element according to any one of (1) to (4), wherein the rotated basic-pattern green sheet is a 180°-rotated basic-pattern green sheet in which the basic-pattern green sheet is rotated by 180°.

(5)

The production method of the electrostatic capacitance element according to (4), wherein the reversed basic-pattern green sheet is a reversed basic-pattern green sheet and/or a 180°-rotated and reversed basic-pattern green sheet that are made by reversing either or both of the basic-pattern green sheet and the 180°-rotated basic-pattern green sheet.

(6)

The production method of the electrostatic capacitance element according to any one of (1) to (4), wherein two masks with different basic patterns for making the basic-pattern green sheet are prepared, and then, two kinds of basic-pattern green sheets, two kinds of 180°-rotated basic-pattern green sheets in which the basic-pattern green sheets are rotated by 180°, and reversed basic-pattern green sheets and/or 180°-rotated and reversed basic-pattern green sheets in which the two kinds of basic-pattern green sheets and the two kinds of 180°-rotated basic-pattern green sheets are respectively reversed, are made.

(7)

The production method of the electrostatic capacitance element according to any one of (1) to (3),

wherein the rotated basic-pattern green sheet comes in three kinds including a 90°-rotated basic-pattern green sheet in which the basic-pattern green sheet is rotated by 90°, a 180°-rotated basic-pattern green sheet in which the basic-pattern green sheet is rotated by 180°, and a 270°-rotated basic-pattern green sheet in which the basic-pattern green sheet is rotated by 270°,

wherein the reversed green sheet comes in four kinds including a reversed basic-pattern green sheet in which the basic-pattern green sheet and the three kinds of rotated basic-pattern green sheets are reversed, a 90°-rotated and reversed basic-pattern green sheet in which the 90°-rotated basic-pattern green sheet is reversed, a 180°-rotated and reversed basic-pattern green sheet in which the 180°-rotated basic-pattern green sheet is reversed, and a 270°-rotated and reversed basic-pattern green sheet in which the 270°-rotated basic-pattern green sheet is reversed, and

wherein the green sheets to be laminated includes eight green sheets and a dielectric sheet on which a conductor is not being applied, the eight green sheets being the basic-pattern green sheet, the 90°-rotated basic-pattern green sheet, the 180°-rotated basic-pattern green sheet, the 270°-rotated basic-pattern green sheet, the reversed basic-pattern green sheet, the 90°-rotated and reversed basic-pattern green sheet, the 180°-rotated and reversed basic-pattern green sheet, and the 270°-rotated and reversed basic-pattern green sheet.

(8)

A production method of an electrostatic capacitance element, including:

preparing a dielectric sheet and a mask that has a predetermined pattern shape for applying a conductor on the dielectric sheet;

making a basic-pattern green sheet by applying the conductor on the dielectric sheet through the mask;

making a 90°-rotated basic-pattern green sheet by rotating the basic-pattern green sheet by 90°;

making a 180°-rotated basic-pattern green sheet by rotating the basic-pattern green sheet by 180°;

making a 270°-rotated basic-pattern green sheet by rotating the basic-pattern green sheet by 270°;

laminating the basic-pattern green sheet, the 90°-rotated basic-pattern green sheet, the 180°-rotated basic-pattern green sheet and the 270°-rotated basic-pattern green sheet; and

laminating a reinforcement white sheet on an upper part and a lower part of the four laminated green sheets and then performing compression-bonding and baking treatments, the reinforcement white sheet being a dielectric sheet on which a conductor is not being applied.

1. A production method of an electrostatic capacitance element, comprising:
preparing a dielectric sheet on which a conductor is not being applied, and a mask that has at least one basic pattern shape for applying the conductor on the dielectric sheet;
making a basic-pattern green sheet by applying the conductor on the dielectric sheet through the mask;
making a rotated basic-pattern green sheet in which the basic-pattern green sheet is rotated;
laminating the basic-pattern green sheet and the rotated basic-pattern green sheet;
making a reversed basic-pattern green sheet by reversing at least one green sheet of the basic-pattern green sheet or the rotated basic-pattern green sheet, the reversed basic-pattern green sheet being different from the basic-pattern green sheet or the rotated basic-pattern green sheet;
laminating the reversed basic-pattern green sheet on a laminate with a dielectric sheet, on which a conductor is not being applied, interposed therebetween, the laminate being resulting from laminating the basic-pattern green sheet and the rotated basic-pattern green sheet; and
performing compression-bonding and baking treatments of a laminate of the basic-pattern green sheet, the rotated basic-pattern green sheet, the dielectric sheet and the reversed basic-pattern green sheet.

2. The production method of the electrostatic capacitance element according to claim 1, further comprising
laminating a reinforcement dielectric sheet on which a conductor is not being applied, on an upper part and a lower part of the laminate of the basic-pattern green sheet, the rotated basic-pattern green sheet, the dielectric sheet and the reversed basic-pattern green sheet.

3. The production method of the electrostatic capacitance element according to claim 1, further comprising
printing an external electrode on a side surface of the laminate of the basic-pattern green sheet, the rotated basic-pattern green sheet, the dielectric sheet and the reversed basic-pattern green sheet, and then performing a baking treatment.

4. The production method of the electrostatic capacitance element according to claim 1, wherein the rotated basic-pattern green sheet is a 180°-rotated basic-pattern green sheet in which the basic-pattern green sheet is rotated by 180°.

5. The production method of the electrostatic capacitance element according to claim 4, wherein the reversed basic-pattern green sheet is a reversed basic-pattern green sheet and/or a 180°-rotated and reversed basic-pattern green sheet that are made by reversing either or both of the basic-pattern green sheet and the 180°-rotated basic-pattern green sheet.

6. The production method of the electrostatic capacitance element according to claim 1, wherein two masks with different basic patterns for making the basic-pattern green sheet are prepared, and then, two kinds of basic-pattern green sheets, two kinds of 180°-rotated basic-pattern green sheets in which the basic-pattern green sheets are rotated by 180°, and reversed basic-pattern green sheets and/or 180°-rotated and reversed basic-pattern green sheets in which the two kinds of basic-pattern green sheets and the two kinds of 180°-rotated basic-pattern green sheets are respectively reversed, are made.

7. The production method of the electrostatic capacitance element according to claim 1,
wherein the rotated basic-pattern green sheet comes in three kinds including a 90°-rotated basic-pattern green sheet in which the basic-pattern green sheet is rotated by 90°, a 180°-rotated basic-pattern green sheet in which the basic-pattern green sheet is rotated by 180°, and a 270°-rotated basic-pattern green sheet in which the basic-pattern green sheet is rotated by 270°,
wherein the reversed green sheet comes in four kinds including a reversed basic-pattern green sheet in which the basic-pattern green sheet and the three kinds of rotated basic-pattern green sheets are reversed, a 90°-rotated and reversed basic-pattern green sheet in which the 90°-rotated basic-pattern green sheet is reversed, a 180°-rotated and reversed basic-pattern green sheet in which the 180°-rotated basic-pattern green sheet is reversed, and a 270°-rotated and reversed basic-pattern green sheet in which the 270°-rotated basic-pattern green sheet is reversed, and
wherein the green sheets to be laminated includes eight green sheets and a dielectric sheet on which a conductor is not being applied, the eight green sheets being the basic-pattern green sheet, the 90°-rotated basic-pattern green sheet, the 180°-rotated basic-pattern green sheet, the 270°-rotated basic-pattern green sheet, the reversed basic-pattern green sheet, the 90°-rotated and reversed basic-pattern green sheet, the 180°-rotated and reversed basic-pattern green sheet, and the 270°-rotated and reversed basic-pattern green sheet.

8. A production method of an electrostatic capacitance element, comprising:
preparing a dielectric sheet and a mask that has a predetermined pattern shape for applying a conductor on the dielectric sheet;
making a basic-pattern green sheet by applying the conductor on the dielectric sheet through the mask;
making a 90°-rotated basic-pattern green sheet by rotating the basic-pattern green sheet by 90°;
making a 180°-rotated basic-pattern green sheet by rotating the basic-pattern green sheet by 180°;
making a 270°-rotated basic-pattern green sheet by rotating the basic-pattern green sheet by 270°;
laminating the basic-pattern green sheet, the 90°-rotated basic-pattern green sheet, the 180°-rotated basic-pattern green sheet and the 270°-rotated basic-pattern green sheet; and
laminating a reinforcement white sheet on an upper part and a lower part of the four laminated green sheets and then performing compression-bonding and baking treatments, the reinforcement white sheet being a dielectric sheet on which a conductor is not being applied.
